(19) United States
(12) Patent Application Publication
(10) Pub. No.: US 2008/0253585 A1
(43) Pub. Date: Oct. 16, 2008

(54) APPARATUS AND METHOD FOR CONTROLLING VOLUME

(75) Inventor: Akinobu Kawamura, Ukyo-Ku (JP)

Correspondence Address: CANTOR COLBURN, LLP, 20 Church Street, 22nd Floor, Hartford, CT, 06103, US

(73) Assignee: ROHM CO., LTD., Kyoto (JP)

(21) Appl. No.: 11/874,583

(22) Filed: Oct. 18, 2007

(30) Foreign Application Priority Data
Oct. 18, 2006 (JP) JP2006-283496

(51) Int. Cl. H03G 3/00

(52) U.S. Cl. 381/107; 381/104

(57) ABSTRACT

A zero-crossing detector detects a zero-crossing point by monitoring an amplitude of an audio signal, and generates a zero-crossing detection signal that becomes a predetermined level for every detected zero-crossing point. A timer circuit counts a clock signal, and generates a timing signal that becomes a predetermined level every time a predetermined unit transition time elapses. A volume setting unit receives the zero-crossing detection signal and the timing signal, and transits the volume from a current value to a target value in a step-wise manner. Every time the timing signal becomes the predetermined level, the volume setting unit changes the volume by a predetermined width at a transition timing at which the zero-crossing detection signal becomes a predetermined level immediately thereafter, and repeats such process to execute volume transition from the current value to the target value.

### BACKGROUND OF THE INVENTION

1. Field of the Invention

The present invention relates to audio signal processing techniques, in particular, to an electronic volume control technique.

2. Description of the Related Art

Audio equipments represented by CD players, MD players, and silicon audio equipments are equipped with a volume controlling apparatus for adjusting volume, that is, amplitude of an audio signal. The volume controlling apparatus sets/changes a volume value based on an instruction from a host processor mounted in the audio equipment.

[Patent document 1] Japanese Patent Application (Laid Open) No. H8-317492

[Patent document 2] Japanese Patent Application (Laid Open) No. 2003-318674

The volume control of the audio signal is executed by changing the amplitude of the audio signal through digital signal processing or analog signal processing. Since change in amplitude becomes discrete when using the electronic volume in this case, the amplitude becomes discontinuous when the volume value is suddenly changed, whereby noise referred to as clicking sound is generated.

### SUMMARY OF THE INVENTION

In view of the above problem, it is a general purpose of the present invention to provide a volume controlling apparatus in which the clicking sound is reduced.

According to an embodiment of the present invention, a volume controlling apparatus which controls volume of an audio signal is provided. The volume controlling apparatus includes a zero-crossing detector which detects a zero-crossing point by monitoring an amplitude of the audio signal, and generates a zero-crossing detection signal that becomes a predetermined level for every detected zero-crossing point; a timer circuit which counts a clock signal, and outputs a timing signal that becomes a predetermined level every time a predetermined time elapses; and a volume setting unit which receives the zero-crossing detection signal, the timing signal and a volume control signal indicating a target value of the volume after change and transits the volume from a current value to a target value in a step-wise manner. Every time the timing signal becomes the predetermined level, the volume setting unit changes the volume by a predetermined width at a transition timing at which the zero-crossing detection signal becomes the predetermined level immediately thereafter, and repeats the process to transit the volume from the current value to the target value.

According to such embodiment, the volume is switched at the time point the amplitude of the audio signal becomes 0, and thus discontinuity of the amplitude by volume switching is reduced, and generation of noise can be suppressed. Furthermore, since the volume transits in a step-wise manner every time a predetermined time elapses, the generation of noise can be further suppressed.

The volume setting unit includes a table which holds a correspondence relationship between volume data indicating the value of the volume and a coefficient to be multiplied to the audio signal when the audio signal is provided as a digital value; a coefficient setting unit which reads the coefficient corresponding to a value of a next volume from the table for every transition timing; and a multiplier which multiplies the coefficient read by the coefficient setting unit and the audio signal.

In one embodiment, the timer circuit receives the zero-crossing detection signal, and may be reset every time the zero-crossing detection signal becomes the predetermined level. In this case, the interval from a transition timing of a certain volume to a transition timing of a next volume is guaranteed to be greater than or equal to a predetermined period, and thus generation of noise can be more suitably suppressed.

In another embodiment, the timer circuit may be reset every time the predetermined time elapses. In this case, the interval from a transition timing of a certain volume to a transition timing of a next volume becomes smaller than a predetermined period, and thus the time required for the volume to transit to the target value can be suitably set.

The zero-crossing detector may monitor a sign bit of a digital value when the audio signal is provided in digital value, and set the zero-crossing detection signal to the predetermined level every time the sign is switched. The zero-crossing can be suitably detected every time the switching of the sign bit is monitored.

The zero-crossing detector may compare an analog value and a predetermined threshold voltage when the audio signal is provided in analog value to set the zero-crossing detection signal to the predetermined level.

The timer circuit may be configured so that the predetermined time is variable using a resistor. In this case, the generated amount of noise can be adjusted taking the balance with the time required for the volume to transit to the target value into consideration.

Another embodiment of the present invention relates to an audio signal amplifying circuit. The audio signal amplifying circuit includes the volume controlling apparatus described above which receives an audio signal and controls an amplitude of the audio signal; a modulator which ΔΣ modulates an output signal of the volume controlling apparatus; and a D-class amplifier which amplifies an output signal of the modulator.

The audio signal amplifying circuit of one embodiment may be integrally integrated on one semiconductor substrate. “Integrally integrated” includes a case in which all the components of the circuit are formed on the semiconductor substrate and a case in which the main components of the circuit are integrally integrated, where some resistor, capacitor, and the like may be arranged outside the semiconductor substrate to adjust the circuit constant. The circuit area can be reduced by integrating as one LSI.

Another further embodiment of the present invention relates to an electronic equipment. The electronic equipment includes the audio signal amplifying circuit; an audio output unit driven by an output signal of the audio signal amplifying circuit; a sound source which generates an audio signal to be amplified by the audio signal amplifying circuit; and a host processor, connected to the audio signal amplifying circuit through a bus, which transmits data indicating a target value of a volume to the audio signal amplifying circuit.

According to such embodiment, the noise output from the audio output unit can be suitably suppressed when changing the volume.

Another further embodiment of the present invention relates to a volume controlling method. The method is a volume controlling method of an audio signal including the steps of detecting a zero-crossing point by monitoring an amplitude of the audio signal and generating a zero-crossing detection signal that becomes a predetermined level for every detected zero-crossing point; counting a clock signal and generating a timing signal that becomes a predetermined level every time a predetermined time elapses; and transiting the volume from a current value to a target value in a step-wise manner based on the zero-crossing detection signal, the timing signal and a volume control signal indicating a target value of the volume after change. The step of transiting the volume includes transiting the volume to the target value by repeating, every time the timing signal becomes the predetermined level, the step of changing the volume by a predetermined width at a transition timing at which the zero-crossing detection signal becomes the predetermined level immediately thereafter.

In one embodiment, the step of generating the timing signal may include starting a measurement of a next predetermined time every time the zero-crossing detection signal becomes the predetermined level. In another embodiment, the step of generating the timing signal may include starting a measurement of a next predetermined time every time the predetermined time elapses.

Another further embodiment of the present invention relates to a method of controlling a volume of an audio signal. The method includes executing volume transition to a target value by repeating the steps of detecting a zero-crossing point by monitoring an amplitude of the audio signal; detecting elapse of a predetermined time; and changing the volume by a predetermined width when the zero-crossing point is detected after the predetermined time has elapsed.

It is to be noted that any arbitrary combination or rearrangement of the above-described structural components and so for this effective as and encompassed by the present embodiments.

Moreover, this summary of the invention does not necessarily describe all necessary features so that the invention may also be a sub-combination of these described features.

### BRIEF DESCRIPTION OF THE DRAWINGS

Embodiments will now be described, by way of example only, with reference to the accompanying drawings which are meant to be exemplary, not limiting, and wherein like elements are numbered alike in several Figures, in which:

FIG. 1 is a circuit diagram showing a configuration of an electronic equipment mounted with an audio signal amplifying circuit according to an embodiment of the present invention;

FIG. 2 is a diagram showing a signal format of volume control data in serial format;

FIGS. 3A and 3B are time charts of volume change in a first mode and a second mode, respectively;

FIG. 4 is a circuit diagram showing a detailed configuration of one part of the electronic volume controlling apparatus according to the embodiment; and

FIG. 5 is a time chart showing the operation of the electronic volume controlling apparatus of FIG. 4.

### DETAILED DESCRIPTION OF THE INVENTION

The invention will now be described based on preferred embodiments which do not intend to limit the scope of the present invention but exemplify the invention. All of the features and the combinations thereof described in the embodiment are not necessarily essential to the invention.

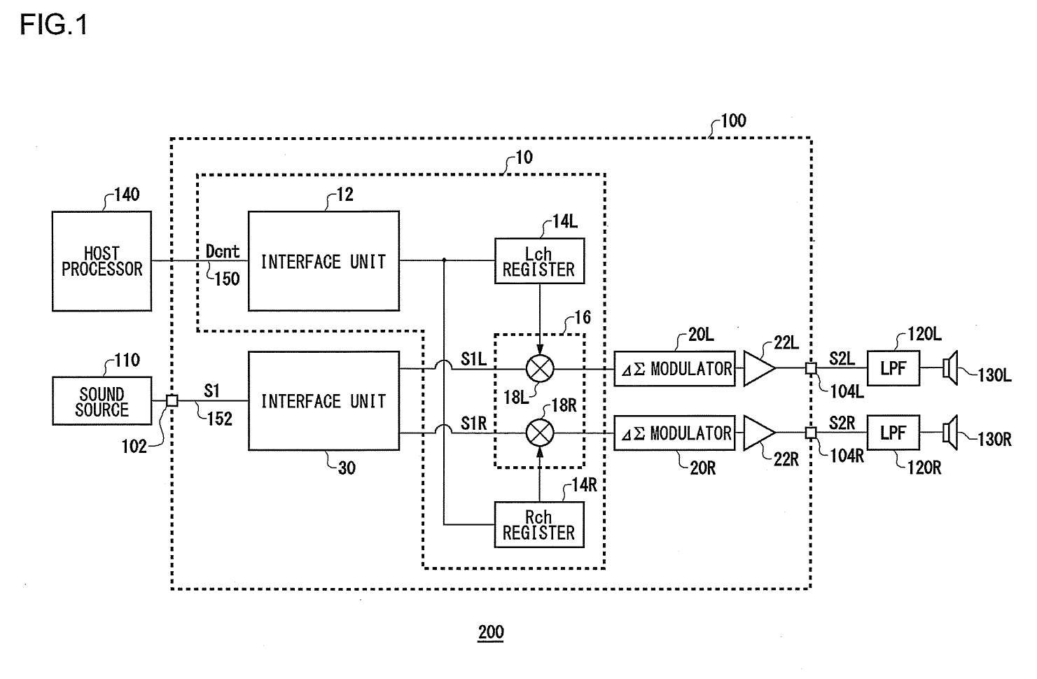

FIG. 1 is a circuit diagram showing a configuration of an electronic equipment 200 mounted with an audio signal amplifying circuit 100 according to an embodiment of the present invention. The audio signal amplifying circuit 100 is mounted on the electronic equipment to which speaker and/or ear phone are/is connected such as portable CD player, portable telephone terminal with music playing function, and outputs audio signal by driving an audio output unit such as speaker and ear phone (referred to as speaker in the following description). The electronic equipment 200 performs a so-called stereo reproduction, and outputs two signals of L channel and R channel.

First, the configuration of the entire electronic equipment 200 will be described. The electronic equipment 200 includes the audio signal amplifying circuit 100, a sound source 110, filters 120L, 120R, and speakers 130L, 130R. The subscript L refers to L channel and R refers to R channel, and the following description is made with the subscript omitted unless particularly required since the L channel and the R channel have the same configuration.

The sound source 110 reads a digital audio signal recorded in a predetermined format in a recording medium such as optical disc, hard disc, and flash memory, decodes the signal, and outputs the signal as signal of digital value. The digital audio signal S1 is input to an input terminal 102 of the audio signal amplifying circuit 100. Although not shown, the audio signal S1 includes signal components of the L channel and the R channel.

The audio signal amplifying circuit 100 receives the audio signal S1 input to the input terminal 102, converts the signal to a bit stream by AZ modulating individually for the L channel and the R channel, and amplifying the same, and furthermore, outputs the resultant from output terminals 104L, 104R. A bit stream audio signal S2 output from the output terminal 104 is input to a filter 120 including an inductor and a capacitor (not shown). The filter 120 removes high frequency component of the bit stream S1. The filter 120 also includes a decoupling capacitor (not shown), removes the DC component of the output signal of the LC filter, and outputs the resultant to the speaker 130. In the present embodiment, the audio signal amplifying circuit 100 is desirably integrally integrated as one functional IC on one semiconductor substrate.

The audio signal amplifying circuit 100 according to the present embodiment can independently change the volume of the L channel and the R channel according to volume control data Dcnt output from a host processor 140. To this end, the audio signal amplifying circuit 100 includes an electronic volume controlling apparatus 10. The configuration of the electronic volume controlling apparatus 10 will be described below with other blocks in the audio signal amplifying circuit 100.

The audio signal amplifying circuit 100 includes the electronic volume controlling apparatus 10, ΔΣ modulators 20L, 20R, D-class amplifiers 22L, 22R, and an interface unit 30.

The audio signal amplifying circuit 100 and the sound source 110 are connected by way of a predetermined bus 152. The sound source 110 sends the audio signal S1 to the audio signal amplifying circuit 100 via the bus 152. The interface unit 30 is an interface for receiving the audio signal S1 sent in a predetermined format from the sound source 110. The interface unit 30 separates the received audio signal S1 to the L channel and the R channel and outputs the signal to the electronic volume controlling apparatus 10 in the post stage.

The electronic volume controlling apparatus 10 multiplies a coefficient corresponding to the volume value to the amplitudes of the audio signals S1L, S1R by digital computing process. The ΔΣ modulator 20 executes an interpolation process and a ΔΣ modulation on the digital audio signal output from the electronic volume controlling apparatus 10. The D-class amplifier 22 is a level shift circuit for amplifying the bit stream output from the ΔΣ modulator 20, and is configured by an inverter having a sufficient transistor size. The bit stream audio signal S2 amplified by the D-class amplifier 22 is input to the filter 120 and output as sound from the speaker 130, as described above.

The electronic volume controlling apparatus 10 according to the present embodiment is connected to the host processor 140 through a serial bus 150, and individually controls the volume of the L channel and the R channel according to the volume control data Dcnt in serial format output from the host processor 140.

The serial bus is an I2C bus in the present embodiment. The electronic volume controlling apparatus 10 includes an interface unit 12, volume registers 14L, 14R, and a volume setting unit 16.

The volume registers 14L, 14R are memories for holding data (hereinafter also referred to as volume data) indicating the volume value for each channel. The interface unit 12 receives the volume control data Dcnt containing volume data for each channel from the external host processor 140 in serial format, and writes the volume data of each channel to the corresponding volume registers 14L, 14R.

The interface unit 12 operates in first and second modes that can be switched. In the first mode, the interface unit 12 writes the volume data to one of the volume registers 14L, 14R corresponding to the channel instructed by the volume control data Dcnt. On the other hand, the interface unit 12 writes the volume data to both the volume registers 14L, 14R in the second mode.

When the data of at least one of the volume registers 14L, 16R is updated, the volume setting unit 16 changes the volume of the channel corresponding to the relevant volume register 14L, 14R. In the present embodiment, the volume setting unit 16 includes multipliers 18L, 18R. Each multiplier 18L, 18R multiplies the digital audio signal S1L, S1R for each channel and the volume value indicated by the volume data stored in the volume register 14L, 14R.

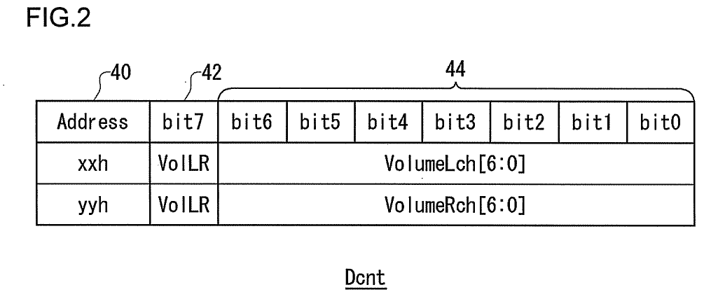

FIG. 2 is a diagram showing a signal format of the volume control data Dcnt in serial format. The volume control data Dcnt includes address data 40 indicating the address of the target register, and mode data 42 and volume data 44 of a total of eight bits. In the data of eight bits, the one bit at the head is the mode data 42 for instructing the first and second mode, and the remaining seven bits are volume data 44 indicating the volume value after change. In the present embodiment, the address data 40 of the register indicates the channel which volume is to be changed. For instance, the volume of the L channel is changed if the address data 40 is xxh, and the volume of the R channel is changed if the address data 40 is yyh.

The mode data 42 for instructing the mode is VolumeLR=0 in the first mode and VolumeLR=1 in the second mode. The volume data 44 of seven bits indicating the volume value controls the volume value in 128 tones. Actually, the multiplier 18 does not multiply the volume data VolumeLch (or VolumeRch) of seven bits and the audio signal S1L (or S1R), but instead, references a table (not shown), acquires a coefficient α corresponding to the volume data VolumeLch (Rch), and multiplies the acquired coefficient α and the audio signal S1L(R).

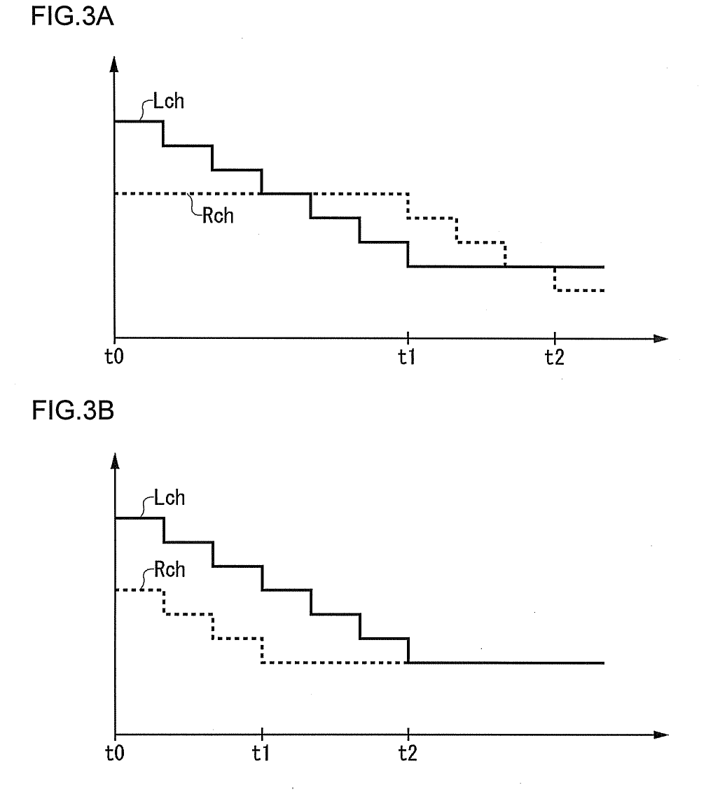

The operation of the electronic volume controlling apparatus 10 configured as above will be described separately for the first mode and the second mode. FIGS. 3A and 3B are time charts of volume change in the first mode and the second mode, respectively. In the time charts shown in FIGS. 3A and 3B, the vertical axis and the horizontal axis are appropriately scaled up or scaled down to simplify the description.

(First Mode)

The interface unit 12 receives the volume control data Dcnt, and references the bit VolLR of the mode data. The first mode is set when VolLR is 0. In the case of the first mode, the interface unit 12 references the address data 40, and stores the volume data 44 in either one of the specified volume register 14L, 14R. When the data of the volume register 14L is updated, the volume setting unit 16 changes the volume value of the L channel.

As shown in FIG. 3A, when receiving the volume control data Dcnt for changing the volume of the L channel at time t0, the interface unit 12 stores the volume value after change in the volume register 14L. The multiplier 18L of the volume setting unit 16 changes the volume in a step-wise manner from the volume value up to this point to the volume value corresponding to the data stored in the volume register 14L. The transition of volume of the L channel is completed at time t1.

When receiving the volume control data Dcnt for changing the volume of the R channel at time t1, the interface unit 12 stores the volume value after change to the volume register 14R. The multiplier 18L of the volume setting unit 16 changes the volume in a step-wise manner from the volume value up to this point to the volume value corresponding to the data stored in the volume register 14L. The transition of volume of the R channel is completed at time t2.

Thus, in the first mode, the volume values of the L channel and the R channel can be independently controlled based on the volume control data Dcnt.

(Second Mode)

The interface unit 12 receives the volume control data Dcnt, and references the bit VolLR of the mode data. The second mode is set when VolLR is 1. In the case of the second mode, the interface unit 12 stores the volume data 44 in both volume registers 14L, 14R. When the data of the volume registers 14L, 14R are updated, the volume setting unit 16 changes the volume values of the L channel and the R channel.

As shown in FIG. 3B, when receiving the volume control data Dcnt for instructing the second mode at time t0, the same volume value is stored in the volume registers 14L, 14R. The multiplier 18L, 18R of the volume setting unit 16 change the volume in step-wise manner from the volume value up to this point to the volume value corresponding to the data stored in the volume registers 14L, 14R. The transition of volume of the R channel is completed at time t1, and the transition of volume of the L channel is completed at time t2.

Therefore, in the second mode, the time lag between the transition of volumes of the two channels can be reduced by starting the transition of volume of the L channel and the R channel at the same timing. Furthermore, the period until the transition of volume for each channel is completed can be reduced.

Since the first mode and the second mode can be switched, the volume value of the L channel or the R channel can be independently changed at different timings based on the volume control data Dcnt, as in the prior art, by setting the mode to the first mode.

As shown in FIG. 3, the electronic volume controlling apparatus 10 according to the present embodiment reduces noise referred to as a so-called clicking sound by transiting the volume values in a step-wise manner. The configuration for transiting the volume will be described below.

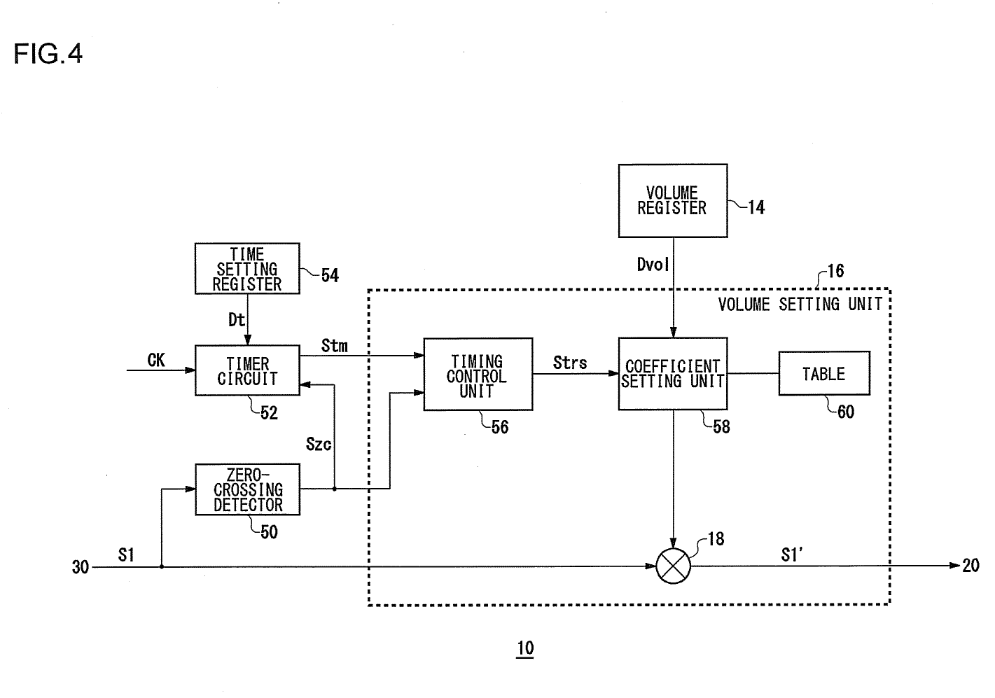

FIG. 4 is a circuit diagram showing a detailed configuration of one part of the electronic volume controlling apparatus 10 according to the embodiment. The electronic volume controlling apparatus 10 includes a zero-crossing detector 50, a timer circuit 52, and a time setting register 54 in addition to the volume register 14 and the volume setting unit 16. Since the electronic volume controlling apparatus 10 is similarly configured by the L channel and the R channel, the subscript of L and R is omitted, and only one will be illustrated.

The zero-crossing detector 50 detects a zero-crossing point by monitoring the amplitude of the audio signal S1. The zero-crossing detector 50 generates a zero-crossing detection signal Szc of a predetermined level (high level) for every timing of the detected zero-crossing point. In the present embodiment, since the audio signal S1 is provided in digital value, the zero-crossing detector 50 monitors the sign bit of the audio signal S1 and sets the zero-crossing detection signal Szc to high level for every switching of the value, that is, the positive and negative sign.

The timer circuit 52 counts a clock signal CK, and generates a timing signal Stm that becomes a predetermined level (high level) every time a predetermined time (hereinafter referred to as unit transition time Tu) elapses. The unit transition time Tu is set based on the time setting data Dt stored in the time setting register 54. The time setting data Dt is used to determine the number of counts of the clock signal CK. That is, the unit transition time Tu can be changed by re-writing the time setting data Dt stored in the time setting register 54. The timer circuit 52 receives the zero-crossing detection signal Szc, and is reset every time the zero-crossing detection signal Szc becomes high level thereby newly starting the count of the clock signal CK.

The volume setting unit 16 receives the zero-crossing detection signal Szc and the timing signal Stm, and transits the volume in a step-wise manner from the current value to the target value. Every time the timing signal Stm becomes high level, the volume setting unit 16 sets the timing at which the zero-crossing detection signal Szc becomes high level to a transition timing immediately thereafter, and changes the volume by a predetermined width for every transition timing. The volume setting unit 16 executes the transition of volume from the current value towards the target value by repeating the relevant process for every transition timing.

Specifically, the volume setting unit 16 includes a timing control unit 56, a coefficient setting unit 58, a table 60, and the multiplier 18. The timing signal Stm and the zero-crossing detection signal Szc are input to the timing control unit 56. Every time the timing signal Stm becomes high level to the transition timing, the timing control unit 56 sets the timing at which the zero-crossing detection signal Szc becomes high level immediately thereafter. The timing control unit 56 generates a transition instructing signal Strs that becomes a predetermined level (high level) for every transition timing. The transition instructing signal Strs is input to the coefficient setting unit 58.

The coefficient setting unit 58 is configured so as to be accessible to the volume register 14 and the table 60. The volume data Dvol indicating the target value of the volume is written to the volume register 14 by the interface unit 12, as described above. The volume data Dvol is data corresponding to the lower 7 bits of the volume control data Dcnt shown in FIG. 2. The correspondence relationship of the volume data Dvol and the coefficient α to be multiplied to the audio signal is stored in the table 60. For instance, the linear coefficient α corresponding to 0 dB to −90 dB is corresponded to the values in which the volume data Dvol is between 0 to 90. The values in which the volume data Dvol is between 91 to 127 corresponds to mute, where the volume is −∞dB, and the value of the linear coefficient α is 0.

The coefficient setting unit 58 holds a variable volx (=0 to 127) corresponding to the current volume value in storage means such as register (not shown). The coefficient setting unit 58 increments or decrements the variable volx corresponding to the current value by a predetermined width Δ towards the target value Dvol every time the transition instructing signal Strs becomes high level with the updating of the value of the volume register 14 as a trigger. The value of the coefficient α corresponding to the current value volx is read from the table 60 and output to the multiplier 18. The predetermined width Δ is, for example, one. In this case, the volume value may transit by 1 dB, which is the minimum width of gain. The predetermined width A may be variably configured using the register.

The multiplier 18 multiplies the coefficient α updated for every transition timing and the audio signal S1, generates the audio signal S1 in which the volume value is adjusted, and outputs the resultant to the ΔΣ modulator 20 of post stage.

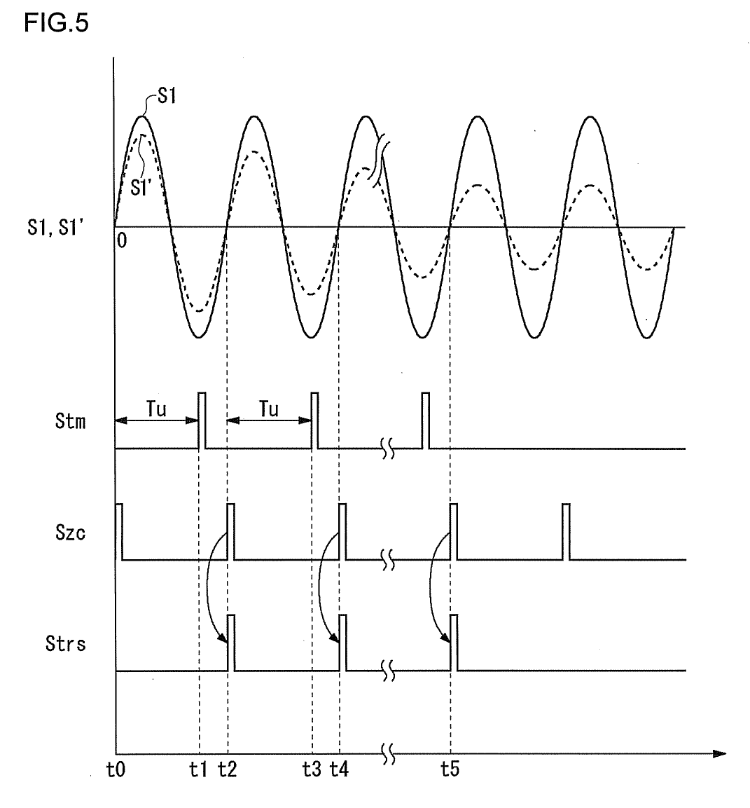

The operation of the electronic volume controlling apparatus 10 configured as above will now be described. FIG. 5 is a time chart showing the operation of the electronic volume controlling apparatus 10 of FIG. 4. FIG. 5 shows the audio signal S1 (solid line) and the audio signal S1′ (broken line), the timing signal Stm, the zero-crossing detection signal Szc, and the transition instructing signal Strs in order from the top. To simplify the description, the audio signals are sinusoidal wave of single amplitude and single frequency in the time chart, but actually, have a more complicating waveform. The horizontal axis and the vertical axis are also appropriately scaled up or scaled down, and does not limit the invention.

When the volume data Dvol of the volume register 14 is updated at time t0, the volume starts to transit. At time t0, the timer circuit 52 starts counting the clock signal CK. After the unit transition time Tu has elapsed at time t1, the timer circuit 52 sets the timing signal Stm to high level. The zero-crossing detection signal Szc becomes high level every time the audio signal S1 crosses zero. The time t2 at which the zero-crossing detection signal Szc becomes high level immediately after the timing signal Stm becomes high level is the transition timing. The coefficient α corresponding to the volume value is updated at time t2 of the transition timing, and the amplitude of the audio signal S1′ is changed.

When the zero-crossing detection signal Szc becomes high level at time t2, the timer circuit 52 is reset, and the count of the clock signal CK starts. After the unit transition time Tu has elapsed at time t3, the timing signal Stm becomes high level, and when the zero-crossing detection signal Szc becomes high level at time t4 following thereto, the transition instructing signal Strs becomes high level, whereby the coefficient α is updated and the amplitude of the audio signal S1′ is changed.

After time t4, the electronic volume controlling apparatus 10 repeats similar processes until the variable volx matches the target value Dvol. The transition is completed when the volume value reaches the target value at time t5, and thereafter, the coefficient α is fixed.

According to the electronic volume controlling apparatus 10 of the present embodiment, the volume is switched by one stage at the time point the amplitude of the audio signal S1 becomes 0, and thus discontinuity of the amplitude by volume switching is reduced, and generation of noise can be suppressed. Furthermore, since the volume transits in a step-wise manner every time the unit transition time Tu elapses, the generation of noise can be further suppressed.

In the present embodiment, the timer circuit 52 receives the zero-crossing detection signal Szc, and is reset every time the zero-crossing detection signal Szc becomes high level. As a result, the generation of noise can be more suitably suppressed since the interval from the transition timing of a certain volume to the transition timing of the next volume is guaranteed to be greater than or equal to the unit transition time Tu, as shown in FIG. 5.

The embodiment is illustrative, and it should be apparent to those skilled in the art that various variants are also possible for the combination of each component and each processing process, and that such variants are also enclosed in the scope of the invention.

In the present embodiment, a case in which the timer circuit 52 is reset by the zero-crossing detection signal Szc has been described, but the present invention is not limited thereto. In another embodiment, the timer circuit 52 may be reset every time the unit transition time Tu elapses. In this case, the timing signal Stm becomes high level for every unit transition time Tu. As a result, the interval from the transition timing of a certain volume to the transition timing of the next volume becomes smaller than the unit transition time Tu, and thus the time required for the volume to transit to the target value can be suitably set.

In the embodiment, a case in which the signal for switching between the first mode and the second mode is contained in the volume control data Dcnt for controlling the volume has been described, but the present invention is not limited thereto. A mode register for holding the current mode may be separately arranged, where the control data for instructing the mode may be generated separate from the volume control data Dcnt, and the data for instructing the mode may be written to the mode register. In this case, when the volume control data Dcnt is input, the volume setting unit 16 determines the current mode with reference to the mode register, and executes write of data to the volume register 14 according to the relevant mode. Effects similar to the electronic volume controlling apparatus 10 according to the embodiment can be obtained in the variant as well since the first mode and the second mode can be switched. Moreover, in this case, the number of bits of the volume control data Dcnt can be reduced since the data for instructing the mode merely needs to be transmitted and received at the timing of switching the modes.

In the electronic volume controlling apparatus 10 according to the embodiment, a case of controlling the volume of audio signal of two channels has been described but may be applied to the audio signal of greater number of channels. In this case, the volume register 14 and the multiplier 18 are arranged for each channel.

In the embodiment, a case of changing the volume value by multiplication through the digital computing process has been described, but the present invention is not limited thereto. The volume may be controlled using a variable gain amplifier or a variable attenuator after converting to the analog audio signal. In this case, the variable gain amplifier or the variable attenuator is arranged in place of the multiplier 18, and the amplification factor or the attenuation factor is changed based on the data corresponding to the volume value stored in the volume register 14. In addition, various methods may be used to change the volume.

While the preferred embodiments of the present invention have been described using specific terms, such description is for illustrative purposes only, and it is to be understood that changes and variations may be made without departing from the spirit or scope of the appended claims.

What is claimed is:

1. A volume controlling apparatus which controls volume of an audio signal; the volume controlling apparatus comprising:
a zero-crossing detector which detects a zero-crossing point by monitoring an amplitude of the audio signal, and generates a zero-crossing detection signal that becomes a predetermined level for every detected zero-crossing point;
a timer circuit which counts a clock signal, and generates a timing signal that becomes a predetermined level every time a predetermined time elapses; and
a volume setting unit which receives the zero-crossing detection signal and the timing signal, and transits the volume from a current value to a target value in a step-wise manner; wherein
every time the timing signal becomes the predetermined level, the volume setting unit changes the volume by a predetermined width at a transition timing at which the zero-crossing detection signal becomes the predetermined level immediately thereafter, and repeats the process to transit the volume from the current value to the target value.

2. The volume controlling apparatus according to claim 1, wherein
the volume setting unit includes,
a table which holds a correspondence relationship between volume data indicating the value of the volume and a coefficient to be multiplied to the audio signal when the audio signal is provided as a digital value;
a coefficient setting unit which reads the coefficient corresponding to a value of a next volume from the table for every transition timing; and
a multiplier which multiplies the coefficient read by the coefficient setting unit and the audio signal.

3. The volume controlling apparatus according to claim 1, wherein
the zero-crossing detector monitors a sign bit of a digital value when the audio signal is provided in digital value and sets the zero-crossing detection signal to the predetermined level every time the sign is switched.

4. The volume controlling apparatus according to claim 1, wherein
the timer circuit receives the zero-crossing detection signal, and is reset every time the zero-crossing detection signal becomes the predetermined level.

5. The volume controlling apparatus according to claim 1, wherein
the timer circuit is reset every time the predetermined time elapses.

6. The volume controlling apparatus according to claim 1, wherein
the timer circuit is configured so that the predetermined time is variable using a resistor.

7. An audio signal amplifying circuit comprising:
the volume controlling apparatus according to claim 1 which receives an audio signal and controls an amplitude of the audio signal;
a modulator which ΔΣ modulates an output signal of the volume controlling apparatus; and
a D-class amplifier which amplifies an output signal of the modulator.

8. The audio signal amplifying circuit according to claim 7, the circuit being integrally integrated on one semiconductor substrate.

9. An electronic equipment comprising:
the audio signal amplifying circuit according to claim 7;
an audio output unit driven by an output signal of the audio signal amplifying circuit;
a sound source which generates an audio signal to be amplified by the audio signal amplifying circuit; and
a host processor, connected to the audio signal amplifying circuit by way of a bus, which transmits data indicating a target value of a volume to the audio signal amplifying circuit.

10. A volume controlling method of an audio signal, the method comprising:
detecting a zero-crossing point by monitoring an amplitude of the audio signal and generating a zero-crossing detection signal that becomes a predetermined level for every detected zero-crossing point;
counting a clock signal and generating a timing signal that becomes a predetermined level every time a predetermined time elapses; and
transiting the volume from a current value to a target value in a step-wise manner based on the zero-crossing detection signal, the timing signal and a volume control signal indicating a target value of the volume after change; wherein
the transiting the volume includes transiting the volume to the target value by repeating, every time the timing signal becomes the predetermined level, the changing the volume by a predetermined width at a transition timing at which the zero-crossing detection signal becomes the predetermined level immediately thereafter.

11. The volume controlling method according to claim 10, wherein
the generating the timing signal includes starting a measurement of a next predetermined time every time the zero-crossing detection signal becomes the predetermined level.

12. The volume controlling method according to claim 10 wherein
the generating the timing signal includes starting a measurement of a next predetermined time every time the predetermined time elapses.

13. A method of controlling a volume of an audio signal; the method comprising:
executing volume transition to a target value by repeating,
detecting a zero-crossing point by monitoring an amplitude of the audio signal;
detecting elapse of a predetermined time; and
changing the volume by a predetermined width when the zero-crossing point is detected after the predetermined time has elapsed.

14. A volume controlling apparatus which controls volume of a plurality of channels, the volume controlling apparatus comprising:
a plurality of registers which holds data indicating a volume value for every channel;
an interface unit which receives data indicating the volume value for every channel in serial format from an external host processor, and writes the data indicating the volume value of the channel to the corresponding register; and
a volume setting unit which, when the value of at least one register is updated, changes the volume of the channel corresponding to the register; wherein
the interface unit operates in a first mode and a second mode that can be switched, writes data indicating the volume value to the register corresponding to the instructed channel in the first mode and writes data indicating the volume value to all the registers in the second mode.

15. The volume controlling apparatus according to claim 14, wherein
the data in serial format includes data instructing first and second modes, data indicating channel to be changed, and data indicating the volume value of the channel.

16. The volume controlling apparatus according to claim 14, wherein
the volume setting unit includes a multiplier which multiplies a digital audio signal for every channel and the volume value indicated by the data stored in the register.

17. An audio signal amplifying circuit comprising:
the volume controlling apparatus according to claim 14 which receives an audio signal of a plurality of channels and controls the volume of each audio signal;
a modulator which ΔΣ modulates an output signal of the volume controlling apparatus; and
a D-class amplifier which amplifies an output signal of the modulator.

18. The audio signal amplifying circuit according to claim 17, the circuit being integrally integrated on one semiconductor substrate.

19. An electronic equipment comprising:
the audio signal amplifying circuit according to claim 17;
an audio output unit driven by an output signal of the audio signal amplifying circuit;
a sound source which generates an audio signal to be amplified by the audio signal amplifying circuit; and
a host processor, connected to the audio signal amplifying circuit through a bus, which transmits data indicating a volume value for every channel to the audio signal amplifying circuit.

20. A volume controlling method which controls volume of a plurality of channels; the method comprising:
receiving data indicating a volume value for every channel in serial format from an external host processor;
writing the data indicating the volume value for every channel to a register corresponding to the channel; and
when the value of at least one register is updated, changing the volume of the channel corresponding to the register;
wherein
in the writing, the data indicating the volume value is written to the register corresponding to the instructed channel in a first mode, and the data indicating the volume value is written to all the registers in a second mode.
